(19) United States
(12) Patent Application Publication
(10) Pub. No.: US 2026/0223631 A1
(43) Pub. Date: Jul. 30, 2026

(54) SUBSTRATE TRANSPORT ROBOT SYSTEM

(71) Applicant: KAWASAKI JUKOGYO KABUSHIKI KAISHA, Kobe-shi, Hyogo (JP)

(72) Inventors: Ryota ONO, Kobe-shi (JP); Hiroki IMANISHI, Kobe-shi (JP)

(73) Assignee: KAWASAKI JUKOGYO KABUSHIKI KAISHA, Kobe-shi, Hyogo (JP)

(21) Appl. No.: 19/143,978

(22) PCT Filed: Dec. 28, 2023
(86) PCT No.: PCT/JP2023/047313

§ 371 Date: Jun. 27, 2025

(30) Foreign Application Priority Data
Dec. 28, 2022 (JP) 2022-211864

(51) Int. Cl. H10P 72/30; B25J 9/10; H10P 72/00; H10P 72/50

(52) U.S. Cl. CPC H10P 72/3302; B25J 9/1015; H10P 72/0606; H10P 72/50

(57) ABSTRACT

A substrate transport robot system includes a substrate holding hand, a robot arm, a drive to serve as a drive source to operate the robot arm in transport operation, and a driven member to transmit a driving force of the drive. The substrate transport robot system also includes a controller configured or programmed to correct a motion of the robot arm in the transport operation based on a shift in an amount of movement in the transport operation caused by a deviation in transmission between the drive and the driven member.

### TECHNICAL FIELD

The present disclosure relates to a substrate transport robot system.

### BACKGROUND ART

Conventionally, a robot system that transports a substrate is known. For example, Japanese Patent Laid-Open No. 2022-102888 discloses a robot system including a substrate transport robot that transports a substrate. The substrate transport robot includes a hand that holds the substrate and a manipulator. The hand is supported at a distal end of the manipulator including a plurality of links. The manipulator includes a joint that connects the plurality of links to each other and a joint motor that drives the joint. Each of the plurality of links rotates around the joint as the joint is rotated by driving of the joint motor. In addition, in the robot system described in Japanese Patent Laid-Open No. 2022-102888, a gear transmission mechanism is arranged between the joint motor and the joint in the substrate transport robot.

When a substrate is transported by a substrate transport robot, the positional accuracy in the substrate transport may be decreased due to gear backlash caused by switching the rotation direction of a joint during a process to move a hand. In contrast, the robot system described in Japanese Patent Laid-Open No. 2022-102888 controls the hand to pass through a set relay position when the substrate is picked up from a predetermined location or when the substrate is placed at a predetermined location. Specifically, the robot system rotates the joint in one direction to place the hand at the relay position, and then rotates the joint in the same direction only to move the hand from the relay position to a position at which the substrate is picked up or a position at which the substrate is placed.

### PRIOR ART

### Patent Document

Patent Document 1: Japanese Patent Laid-Open No. 2022-102888

### SUMMARY OF THE INVENTION

However, when the substrate is transported via the relay position in order to reduce or prevent a decrease in the positional accuracy, as in the robot system described in Japanese Patent Laid-Open No. 2022-102888, the movement distance of the substrate may conceivably increase due to restriction of the movement direction in the substrate transport operation. In such a case, the time required for the transport operation conceivably increases due to the increase in the movement distance of the substrate. Therefore, it is desired to reduce or prevent an increase in the time required for the transport operation while reducing or preventing a decrease in the accuracy of the substrate transport operation.

The present disclosure is intended to solve the above problems. The present disclosure aims to provide a substrate transport robot system capable of reducing or preventing an increase in the time required for the transport operation while reducing or preventing a decrease in the accuracy of the substrate transport operation.

A substrate transport robot system according to an aspect of the present disclosure includes a substrate holding hand to hold a substrate, a robot arm attached to the substrate holding hand, a drive to serve as a drive source to operate the robot arm in transport operation of the robot arm, the transport operation including at least one of placement operation to place the substrate on a mount or holding operation to hold the substrate from the mount, a driven member to transmit a driving force of the drive to operate the robot arm, and a controller configured or programmed to correct a motion of the robot arm in the transport operation based on a shift in an amount of movement in the transport operation caused by a deviation in transmission between the drive and the driven member.

As described above, the substrate transport robot system according to this aspect of the present disclosure includes the controller configured or programmed to correct the motion of the robot arm in the transport operation based on the shift in the amount of movement in the transport operation caused by the deviation in transmission between the drive and the driven member. Accordingly, even when the deviation in transmission between the drive and the driven member, such as backlash, occurs, a decrease in the positional accuracy of the transport operation can be reduced or prevented by correcting the motion of the robot arm in the transport operation based on the shift in the amount of movement in the transport operation caused by the deviation in transmission. Therefore, a decrease in the accuracy of the motion of the robot arm can be reduced or prevented without restricting the movement direction in the transport operation as in a case of passing through a preset relay position, and thus a decrease in the accuracy of the motion of the robot arm can be reduced or prevented while an increase in the movement distance of the substrate in the transport operation is reduced or prevented. Consequently, an increase in the time required for the transport operation can be reduced or prevented while a decrease in the accuracy of the substrate transport operation is reduced or prevented.

According to the present disclosure, it is possible to reduce or prevent an increase in the time required for the transport operation while reducing or preventing a decrease in the accuracy of the substrate transport operation.

### BRIEF DESCRIPTION OF THE DRAWINGS

FIG. 1 is a schematic view showing the overall configuration of a substrate processing system including a substrate transport robot system according to a first embodiment.

FIG. 2 is a block diagram showing the configuration of the substrate processing system including the substrate transport robot system.

FIG. 3 is a perspective view schematically showing the substrate transport robot system.

FIG. 4 is a schematic view for illustrating the configuration of a drive and a driven member.

FIG. 5 is a schematic view for illustrating detection of a substrate by detectors.

FIG. 6 is a diagram for illustrating a shift in the amount of movement.

FIG. 7 is a diagram for illustrating correction based on the shift in the amount of movement.

FIG. 8 is a diagram for illustrating motion correction in a fine adjustment control.

FIG. 9 is a diagram for illustrating motion correction during normal operation.

FIG. 10 is a flowchart for illustrating a control process of a substrate transport method by the substrate transport robot system.

FIG. 11 is a schematic view for illustrating a substrate holding hand according to a second embodiment.

FIG. 12 is a diagram for illustrating correction based on a shift in the amount of movement according to the second embodiment.

FIG. 13 is a schematic view for illustrating processing modules according to a modified example of the second embodiment of the present disclosure.

### MODES FOR CARRYING OUT THE INVENTION

### First Embodiment

A first embodiment embodying the present disclosure is hereinafter described on the basis of the drawings.

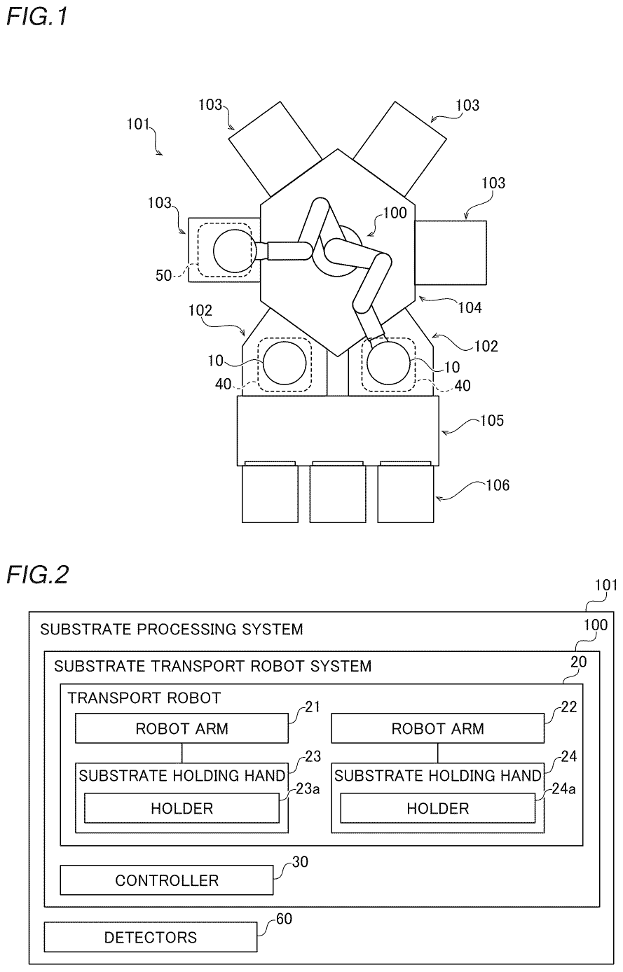

The configuration of a substrate transport robot system 100 according to a first embodiment is now described with reference to FIGS. 1 to 9.

### Configuration of Substrate Processing System

As shown in FIG. 1, the substrate transport robot system 100 according to the first embodiment transports substrates 10 in a substrate processing system 101. The substrate processing system 101 includes the substrate transport robot system 100, load locks 102, and a plurality of processing modules 103. In an example of FIG. 1, the substrate processing system 101 includes four processing modules 103. The substrate processing system 101 also includes a transport chamber 104 and a loading/unloading chamber 105. The substrate processing system 101 performs a process on the substrates 10 such as semiconductor wafers or printed circuit boards. The substrates 10 are, for example, glass substrates or silicon substrates having a substantially disk shape.

Each of the processing modules 103 performs a process such as resist coating or etching on the substrate 10. The plurality of processing modules 103 are arranged along the outer periphery of the transport chamber 104. The inside of the transport chamber 104 is maintained at a predetermined vacuum level. In other words, the substrate processing system 101 is a multi-chamber type vacuum processing apparatus. The load locks 102 are provided on the outer periphery of the transport chamber 104. The loading/unloading chamber 105 is provided on the opposite side of the load locks 102 to the transport chamber 104. Three ports are provided on the opposite side of the loading/unloading chamber 105 to the load locks 102 to attach carriers 106 capable of accommodating the substrates 10.

The substrate transport robot system 100 unloads the substrates 10 from the processing modules 103 in which the process is performed on the substrates 10, and loads the substrates 10 into the processing modules 103. In the substrate processing system 101, a transport robot (not shown) arranged in the loading/unloading chamber 105 loads the substrates 10 from the carriers 106 into the load locks 102. Then, the substrate transport robot system 100 according to the first embodiment transports the substrates 10 from the load locks 102 to the plurality of processing modules 103. The substrate 10 that has been processed in each of the plurality of processing modules 103 is transported from each of the plurality of processing modules 103 to the load lock 102 by the substrate transport robot system 100. The processed substrate 10 is then unloaded from the load lock 102 to the carrier 106 by the transport robot (not shown) arranged in the loading/unloading chamber 105. The carriers 106 store a plurality of substrates 10. In the load locks 102, the substrates 10 are placed on mounts 40. In each of the plurality of processing modules 103, the substrate 10 is placed on a mount 50.

### Configuration of Substrate Transport Robot System

As shown in FIG. 2, the substrate transport robot system 100 includes a transport robot 20 and a controller 30. The transport robot 20 includes a robot arm 21 and a robot arm 22. A substrate holding hand 23 and a substrate holding hand 24 are attached to the robot arm 21 and the robot arm 22, respectively. The transport robot 20 is arranged substantially in the center of the transport chamber 104. The robot arm 21 and the robot arm 22 are examples of a first robot arm and a second robot arm, respectively.

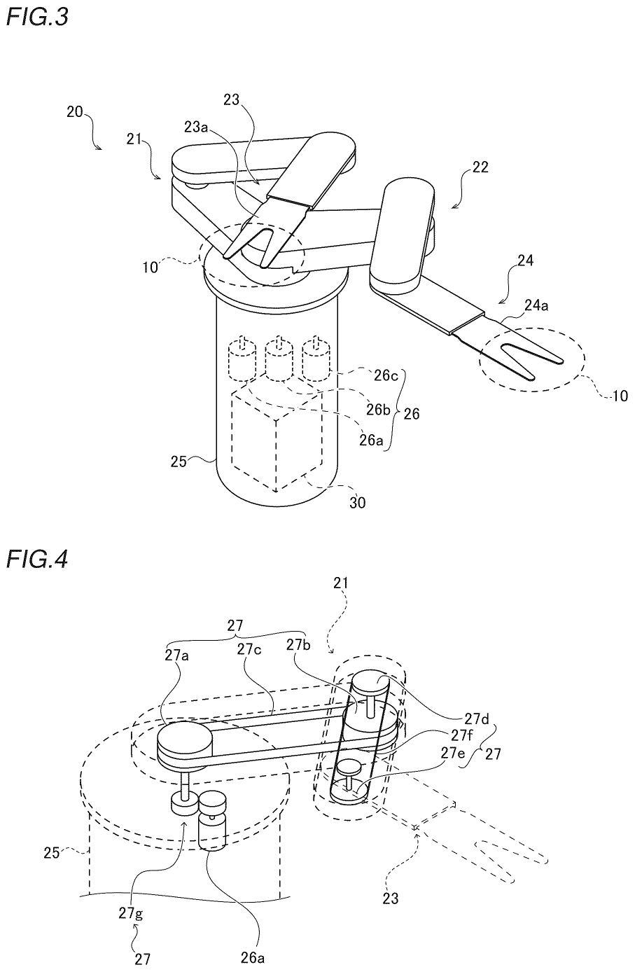

The controller 30 is a computer including a central processing unit (CPU), a random access memory (RAM), and a read-only memory (ROM), for example. The controller 30 also includes a storage including a flash memory such as a solid state drive (SSD). The controller 30 may be spaced apart from the transport robot 20, or may be arranged integrally with the transport robot 20. For example, the controller 30 is arranged in a base 25 (described below) shown in FIG. 3. The controller 30 controls the operation of each portion of the substrate transport robot system 100 based on a program and parameters stored in the storage in advance. The controller 30 is a robot controller that controls the transport operation of each of the robot arms 21 and 22 that transport a plurality of substrates 10. The controller 30 controls the transport operation to transport the plurality of substrates 10 based on control signals from a higher-level control device that controls the entire substrate processing system 101. The control of the transport operation by the controller 30 is described below in detail.

As shown in FIG. 3, the transport robot 20 is a horizontal articulated wafer transport robot that loads and unloads the substrates 10 between the load locks 102 and the processing modules 103. Each of the robot arms 21 and 22 rotates, extends, and retracts by driving a plurality of joints. The robot arms 21 and 22 operate separately from each other by a control process of the controller 30. Specifically, each of the robot arms 21 and 22 includes two arms connected to each other. The substrate holding hand 23 and the substrate holding hand 24 are attached on the distal end sides, which are first ends, of the two mutually connected arms of the robot arms 21 and 22, respectively, and the robot arms 21 and 22 are connected to the common base 25 on the base end sides, second ends, of the two mutually connected arms. Each of the robot arms 21 and 22 rotates, extends, and retracts separately with respect to the base 25.

The substrate holding hands 23 and 24 include holders 23a and 24a that each hold one substrate 10, respectively. Each of the holders 23a and 24a is a thin support plate that supports the substrate 10. Each of the holders 23a and 24a supports the rear surface of the substantially disk-shaped substrate 10 from below in the vertical direction. The substrate holding hands 23 and 24 do not include actuators or the like that drive the holders 23a and 24a to fix the substrates 10 held by the holders 23a and 24a, and are passive-type end effectors that support the substrates 10 from below in the vertical direction without fixing the substrates 10.

The substrate transport robot system 100 transports the substrate 10 held by the substrate holding hand 23 by operating the robot arm 21. Similarly, the substrate transport robot system 100 transports the substrate 10 held by the substrate holding hand 24 by operating the robot arm 22. The configuration of the substrate holding hand 23 and the configuration of the substrate holding hand 24 are common to each other.

The transport robot 20 also includes a drive 26 as a drive source to operate the robot arms 21 and 22. The drive 26 includes motors 26a, 26b, and 26c that perform rotational operation as drive sources to operate the robot arms 21 and 22 in the transport operation. The motors 26a, 26b, and 26c include, for example, servomotors that perform rotational operation under the control of the controller 30. The transport robot 20 also includes an encoder that acquires the number of rotations of each of the motors 26a, 26b, and 26c. The controller 30 controls the operation of each of the motors 26a, 26b, and 26c by a feedback control based on an output from the encoder to control the motion of each of the robot arms 21 and 22.

The motors 26a, 26b, and 26c are arranged in the base 25. For example, the motors 26a and 26b serve as drive sources for the extending and retracting motions of the robot arms 21 and 22, respectively. That is, the motor 26a serves as a drive source for the bending and extending motion of the arms of the robot arm 21 and for the rotating motion of the substrate holding hand 23 with respect to the robot arm 21. The motor 26b serves as a drive source for the bending and extending motion of the arms of the robot arm 22 and for the rotating motion of the substrate holding hand 24 with respect to the robot arm 22. The motor 26c serves as a drive source for the rotating motions of the robot arms 21 and 22 with respect to the base 25. Therefore, in the transport robot 20, the robot arms 21 and 22 have a total of three degrees of freedom. That is, the robot arms 21 and 22 are controlled to be freely driven in three types of motions without affecting each other. In addition, a linear motion mechanism is provided in the base 25 to vertically raise and lower each of the robot arms 21 and 22 separately. This linear motion mechanism includes a servomotor as a drive source, for example.

As shown in FIG. 4, the transport robot 20 includes a plurality of driven members 27. The driven members 27 transmit the driving forces of the motors 26a, 26b, and 26c of the drive 26 to operate each of the robot arms 21 and 22. The driven members 27 include a pulley 27a, a pulley 27b, a belt 27c, a pulley 27d, a pulley 27e, and a belt 27f, for example. The pulley 27a, the pulley 27b, the belt 27c, the pulley 27d, the pulley 27e, and the belt 27f are arranged inside the robot arm 21 and transmit the driving force of the motor 26a arranged in the base 25. The pulley 27a, the pulley 27b, the belt 27c, the pulley 27d, the pulley 27e, and the belt 27f are interlocked with each other such that the joints of the robot arm 21 and the substrate holding hand 23 are driven in conjunction with each other. Specifically, the pulley 27a is arranged on the proximal end side of the robot arm 21. The pulley 27a rotates by the driving force transmitted from the motor 26a. When the pulley 27a rotates, the pulley 27b rotates via the belt 27c. The pulleys 27b and 27d rotate integrally. Therefore, the rotation of the pulley 27b is transmitted from the pulley 27d to the pulley 27e via the belt 27f. The belts 27c and 27f are made of metal such as stainless steel. The belts 27c and 27f may be made of a material other than metal, such as rubber. The driven members 27 also include a gear 27g arranged in the base 25, for example. The gear 27g transmits the driving force of the motor 26a to the pulley 27a.

Although not shown in FIG. 4, driven members 27 that transmit the driving force of the motor 26b of the drive 26 are also arranged in the robot arm 22. A driven member 27 that transmits the driving force of the motor 26b to the robot arm 22 is also arranged in the base 25. Similarly, driven members 27 that transmit the driving force of the motor 26c to the robot arms 21 and 22 are also arranged in the base 25. The driven members 27 that transmit the driving force of the drive 26 may transmit the driving force of the drive 26 via a plurality of gears instead of a belt pulley structure.

As shown in FIG. 1, for example, each of the plurality of processing modules 103 is configured to process the substrates 10 one by one. That is, in each of the plurality of processing modules 103, the substrates 10 are placed one by one on the mount 50. A pair of load locks 102 are arranged in the substrate processing system 101, and in each load lock 102, the substrates 10 are placed one by one on the mount 40. The mounts 40 and 50 each include, for example, a pin-shaped member or a table-shaped member that holds the substrate 10.

The substrate transport robot system 100 transports the substrates 10 one by one between the load locks 102 and each of the plurality of processing modules 103 by independently operating the two robot arms 21 and 22.

### Detector

As shown in FIG. 2, the substrate processing system 101 includes detectors 60. The detectors 60 detect the substrate 10 held by each of the substrate holding hands 23 and 24 of the transport robot 20. The detectors 60 detect the substrate 10 for each of the robot arms 21 and 22.

As shown in FIG. 5, specifically, the detectors 60 include a plurality of transmissive laser sensors. The detectors 60 include, as the transmissive laser sensors, light emitters including light sources such as light-emitting diodes (LEDs) that emit laser light, and light receivers including light-receiving elements such as charge coupled device (CCD) image sensors. For example, the detectors 60 are arranged on the sides of the load locks 102 and on each side of the plurality of processing modules 103 in the transport chamber 104 of the substrate processing system 101. The detectors 60 are arranged such that a position through which the substrate 10 passes during the transport operation with respect to the mount 40 or the mount 50 is a detection target area. That is, the detectors 60 are disposed so as to detect the position through which the substrate 10 passes before the mount 40 or the mount 50 when the substrate 10 held by each of the substrate holding hands 23 and 24 is transported toward the mount 40 or the mount 50.

Two detectors 60 are arranged for each of the mounts 40 and 50 on which one substrate 10 is to be placed. That is, a pair of detectors 60, each of which is a transmissive laser sensor including a pair of a light emitter and a light receiver, are arranged for each mount 40 or for each mount 50, on which one substrate 10 is to be placed. In the substrate processing system 101, one substrate 10 is detected by a pair of detectors 60. For example, in the example of FIG. 1, one substrate 10 is transported to each of the four processing modules 103 and two load locks 102. Therefore, in the substrate processing system 101, two detectors 60 are arranged for each of the four processing modules 103 and the two load locks 102, and a total of twelve detectors 60 are arranged. Each of a plurality of detectors 60 outputs a detection result indicating that the substrate 10 has been detected to the controller 30. Although FIG. 5 illustrates an example in which the substrate 10 is transported by the substrate holding hand 23, the same applies to transport by the substrate holding hand 24.

Specifically, the controller 30 calculates the positions of four points on the periphery of one substrate 10 based on the detection results from the pair of detectors 60. By each of the detectors 60, which are transmissive laser sensors, two points are detected: a point at which the laser light is switched from a transmitted state to a light blocked state due to the passage of the substrate 10, and a point at which the laser light is switched from the light blocked state to the transmitted state. The controller 30 stores in advance the positions that are the detection targets of the detectors 60. The controller 30 acquires the positions of the four points on the periphery of the substrate 10 by acquiring the positions that are the detection targets of the detectors 60 and a speed at which the substrate holding hand 23 is moved. Then, the controller 30 calculates the position of the substrate 10 based on the acquired positions of the four points.

### Details of Control of Transport Operation by Controller

In the first embodiment, the controller 30 controls the transport operation of each of the robot arms 21 and 22, including the placement operation to place the substrate 10 on the mount 40 and the mount 50, and the holding operation to hold the substrate 10 from the mount 40 and the mount 50. The controller 30 acquires command values for controlling the transport operation of each of the robot arms 21 and 22. Then, the controller 30 controls the operation of the drive 26 based on the acquired command values to control the motions of the robot arms 21 and 22. The command values may be acquired based on control signals from a higher-level control device, or may be acquired based on setting values and parameters stored in advance in the storage included in the controller 30, for example. The command value is, for example, a command value for controlling the speed or acceleration of each of the motors 26a, 26b, and 26c. The command value may be, for example, a command value for controlling the torque of each of the motors 26a, 26b, and 26c.

### Position Correction Control

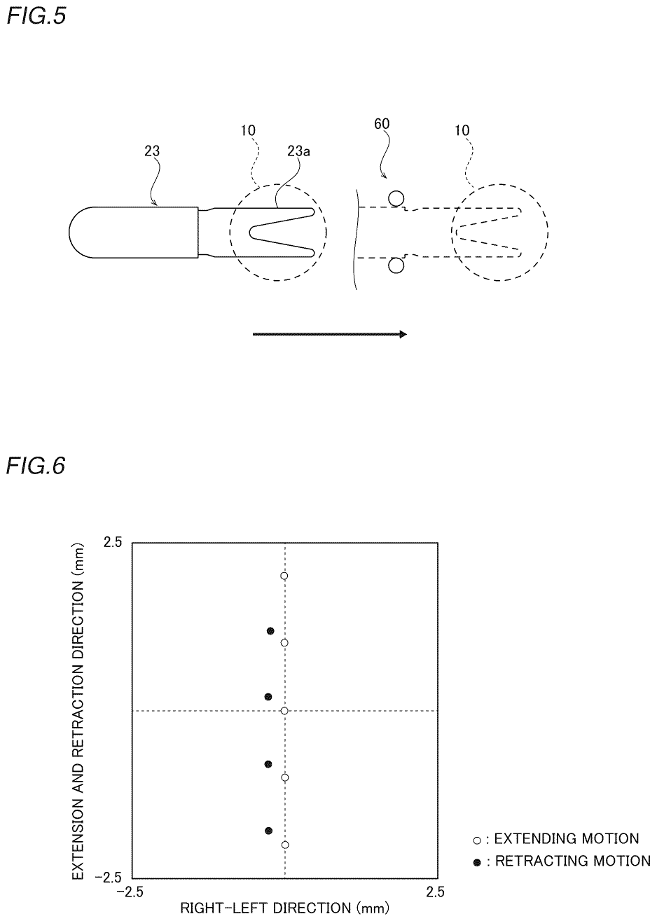

As shown in FIG. 6, when the rotation direction of the motor 26a of the drive 26 is reversed to change the direction of motion of the robot arm 21, backlash or lost motion, which is a deviation in transmission between the drive 26 and the driven members 27, may occur. This deviation in transmission of the driving force may cause the motion of the robot arm 21 to become inaccurate. FIG. 6 shows the position of the substrate holding hand 23 when the robot arm 21 is extended by a predetermined distance by driving of the motor 26a, and then the rotation direction of the motor 26a of the drive 26 is reversed to retract the robot arm 21 by the same predetermined distance as the extension. The term “extend” refers to extending the two arms of the robot arm 21 so as to increase an angle between the arms, and the term “retract” refers to folding the two arms so as to reduce the angle between the arms. The position indicated by a white circle in FIG. 6 indicates the position of the substrate holding hand 23 detected for each command to extend the robot arm 21 by the predetermined distance in the extending motion. The position indicated by a black circle in FIG. 6 indicates the position of the substrate holding hand 23 detected for each command to retract the robot arm 21 by the predetermined distance in the retracting motion following the extending motion. Thus, the deviation in transmission of the driving force occurs between the drive 26 and the driven members 27 due to various factors such as a mechanical gap, friction, deformation such as member elongation, and slippage. Due to this deviation in transmission, even when the motor 26a is rotated a predetermined number of times based on the set command value, it becomes difficult to accurately place the substrate holding hand 23 at the position indicated by the command value. For example, when the predetermined distance is 1 mm, the substrate holding hand 23 moves to a position substantially the same as the position corresponding to the command value in the extending motion, whereas the substrate holding hand 23 moves to a position deviated by a distance smaller than 1 mm from the position corresponding to the command value in the retracting motion. That is, as an example, a shift in the amount of movement in the transport operation caused by the deviation in transmission between the drive 26 and the driven members 27 is a value smaller than 1 mm.

In the first embodiment, the controller 30 corrects the motion of each of the robot arms 21 and 22 in the transport operation based on the shift in the amount of movement in the transport operation caused by the deviation in transmission between the drive 26 and the driven members 27. Specifically, the controller 30 acquires the shift in the amount of movement in the transport operation based on the detection results obtained by the detectors 60. The controller 30 acquires a shift in the amount of movement to correspond to each of a plurality of degrees of freedom of the motions of the robot arms 21 and 22. That is, because the degrees of freedom of the robot arms 21 and 22 are three, the controller 30 acquires three shifts. Furthermore, the controller 30 acquires the shift in the amount of movement that occurs when the directions of motion of the robot arms 21 and 22 are changed in each of the three degrees of freedom. That is, the controller 30 acquires the shift in the amount of movement that occurs when the rotation directions of the motors 26a, 26b, and 26c are reversed in order to change the directions of motion of the robot arms 21 and 22.

For example, the controller 30 acquires the shift in the amount of movement in the extending and retracting motion of the robot arm 21. In such a case, the controller 30 acquires the detection results obtained by the detectors 60 when the motor 26a of the drive 26 is rotated to a first side so as to extend the robot arm 21. The controller 30 also acquires the detection results obtained by the detectors 60 when the motor 26a of the drive 26 is rotated to a second side opposite to the first side so as to retract the robot arm 21. Then, the controller 30 calculates the shift in the amount of movement based on the acquired detection results in the extending motion and the acquired detection results in the retracting motion. Similarly, the controller 30 acquires the shift in the amount of movement in the extending and retracting motion of the robot arm 22. Then, the controller 30 acquires the shift in the amount of movement based on the detection results obtained when the rotating motion of either the robot arm 21 or the robot arm 22 is performed. Thus, the controller 30 acquires the shift in the amount of movement in the same or more number of motions as the number of degrees of freedom.

The controller 30 calculates three correction amounts corresponding to the three degrees of freedom, respectively, based on the acquired three shifts in the amount of movement. That is, the controller 30 calculates a correction amount to correct the shift that occurs when the rotation direction is reversed for each of the three motors 26a, 26b, and 26c of the drive 26. The calculated correction amount is stored in the storage of the controller 30. When the shift in the amount of movement is measured to calculate the correction amount, only one of the motors 26a, 26b, and 26c may be operated, or a combination of a plurality of motors may be operated. For example, when the degrees of freedom are three, the correction amount for each of the three degrees of freedom is calculated by calculating the shift in the amount of movement by three or more motions. A control to acquire the shift in the amount of movement to calculate the correction amount may be performed when the substrate transport robot system 100 is installed, or may be performed periodically, such as every time a predetermined period of time has elapsed or every time a predetermined number of starts are performed.

The controller 30 corrects the motions of the robot arms 21 and 22 for each of the plurality of degrees of freedom, using the correction amount calculated based on the shift acquired for each of the plurality of degrees of freedom. Specifically, when controlling rotation of the motors 26a, 26b, and 26c of the drive 26 based on the command values, the controller 30 corrects the command values based on the calculated correction amounts at the timing at which the robot arms 21 and 22 are operated such that the rotation directions are reversed. For example, when the correction amount for rotation of the motor 26a is 1 degree and a command is acquired to rotate the motor 26a 5 degrees to the first side and then rotate the motor 26a 3 degrees to the second side, the controller 30 corrects the angle of rotation to the second side to 4 degrees by adding the correction amount to the command for the second side.

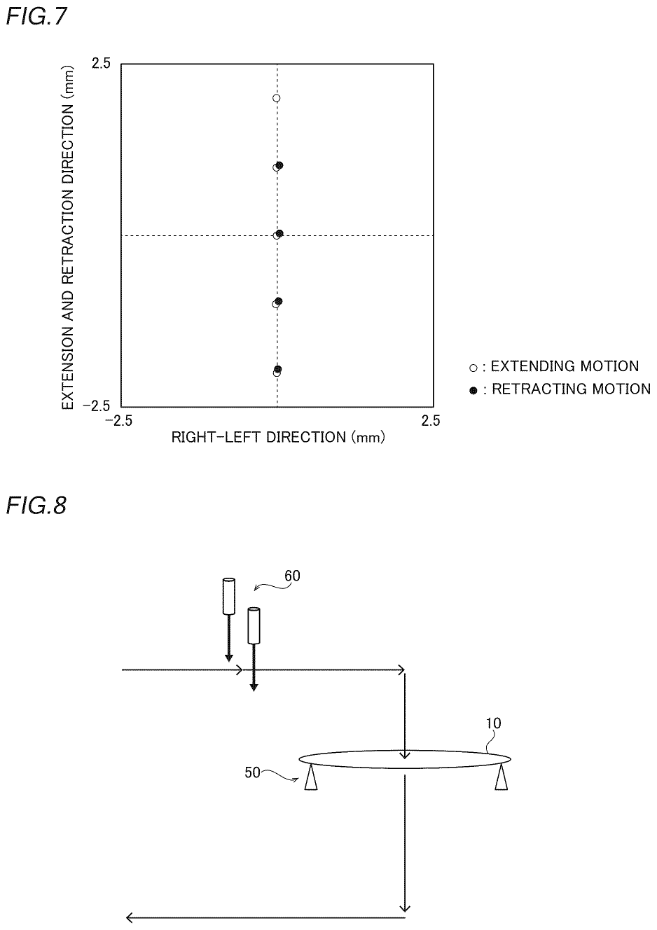

As shown in FIG. 7, in a state in which the motions of the robot arms 21 and 22 are corrected, the shift in the amount of movement between the extending motion and the retracting motion is reduced or prevented, and a decrease in the accuracy of the motions of the robot arms 21 and 22 is reduced or prevented. FIG. 7 shows the position of the substrate holding hand 23 when, in a state in which the command value is corrected based on the calculated correction amount, the robot arm 21 is extended by the predetermined distance by driving of the motor 26a, and then the rotation direction of the motor 26a of the drive 26 is reversed to retract the robot arm 21 by the same predetermined distance as the extension, as in the operation of FIG. 6. That is, the position indicated by a white circle in FIG. 7 indicates the position of the substrate holding hand 23 detected for each command to extend the robot arm 21 by the predetermined distance based on the corrected command value in the extending motion. The position indicated by a black circle in FIG. 7 indicates the position of the substrate holding hand 23 detected for each command to retract the robot arm 21 by the predetermined distance based on the corrected command value in the retracting motion following the extending motion. Thus, even when motions are performed in which rotation of the motor 26a, the motor 26b, and the motor 26c is reversed, a decrease in the accuracy of the motions of the robot arms 21 and 22 is reduced or prevented by correcting the motion command values using the correction amounts calculated based on the shifts, as compared with a case in which the correction is not performed.

### Correction in Fine Adjustment Control

As shown in FIG. 8, the controller 30 performs a fine adjustment control to finely adjust the motions of the robot arms 21 and 22 in the transport operation based on the detection results detected by the detectors 60. Then, the controller 30 corrects the motions of the robot arms 21 and 22 in the fine adjustment control.

The controller 30 performs a fine adjustment control when the substrate 10 is placed. The controller 30 performs the transport operation to transport the substrates 10 one by one based on a preset command value. When the substrate 10 is placed on the mount 40 or the mount 50 in the transport operation, the held substrate 10 may be misaligned with respect to the substrate holding hand 23 or the substrate holding hand 24. That is, even when the substrate 10 is transported according to the command value, the substrate 10 may not be accurately placed on the mount 40 or the mount 50 due to the misalignment. In this regard, the controller 30 calculates the misalignment of the substrate 10 held by the substrate holding hand 23 or the substrate holding hand 24 based on the detection results of the detectors 60, and performs a fine adjustment control to correct the command value to compensate for the misalignment. The calculated “misalignment” includes the magnitude and direction of the misalignment of the substrate 10 with respect to the substrate holding hand 23 or the substrate holding hand 24 along the horizontal plane.

For example, while the substrate 10 is being transported toward the mount 50, the controller 30 corrects the command value to compensate for the misalignment of the substrate 10 based on the detection results of the detectors 60. Then, the controller 30 controls the motion of the robot arm 21 or the robot arm 22 based on the corrected command value to place the substrate 10 on the mount 50. The controller 30 places the substrate 10 on the mount 50 by lowering the substrate holding hand 23 or the substrate holding hand 24 while aligning the position of the substrate 10 on the horizontal plane with the position of the mount 50. In such a case, when the rotation directions of the motors 26a, 26b, and 26c of the drive 26 are reversed when the motion of the robot arm 21 or the robot arm 22 is controlled, the controller 30 further corrects the command value corrected based on the detection results, based on the correction amounts calculated from the shifts. Thus, the substrate 10 is placed on the mount 50 with the position of the substrate 10 on the horizontal plane with respect to the mount 50 accurately fine-tuned.

Even in the holding operation to hold the substrate 10 placed on the mount 50, the substrate 10 placed on the mount 50 may be imaged by an imager such as an optical camera such that the misalignment of the substrate 10 placed on the mount 50 is detected, and the substrate 10 is held while a fine adjustment control is performed based on the detected misalignment. In such a case, too, the controller 30 further corrects the command value, which is a control amount in the fine adjustment control, using the correction amount calculated based on the shift when the rotation direction of the motor 26a, the motor 26b, or the motor 26c is reversed to change the direction of motion of the robot arm 21 or the robot arm 22 in the fine adjustment control.

### Correction During Normal Transport

As shown in FIG. 9, even during normal transport, the controller 30 corrects the motions of the robot arm 21 and the robot arm 22 by correcting the command values based on the acquired shift in the amount of movement during the transport operation. For example, when the substrate transport robot system 100 is installed, the controller 30 acquires command values for operating the robot arm 21 and the robot arm 22 based on input operations by a user that teaches the motions of the robot arm 21 and the robot arm 22 in the transport operation. Then, in the substrate 10 transport operation, the controller 30 corrects the acquired command values based on the correction amounts calculated from the shift in the amount of movement when motions are included in which the rotation directions of the motor 26a, the motor 26b, and the motor 26c of the drive 26 are reversed when the drive 26 is operated based on the acquired command values.

For example, when the robot arm 21 is to extend or retract, the controller 30 calculates a command value for controlling the speed and acceleration of the motor 26a based on the motions of the robot arm 21 and the robot arm 22 taught by the user. In such a case, the controller 30 corrects the command value based on the shift in the amount of movement caused by the deviation in transmission between the drive 26 and the driven members 27 at the timing at which the command value of the speed command is switched between positive and negative. That is, the controller 30 corrects the acquired command value based on the shift when a motion is included in which the rotation direction of the motor 26a is reversed to control the extending and retracting motion of the robot arm 21 such that the taught motion is performed in a state in which the deviation in transmission between the drive 26 and the driven members 27 is cancelled. When the rotation direction of the motor 26a is reversed, a delay occurs between the rotation of the motor 26a and the actual motion of the robot arm 21 due to the deviation in transmission between the drive 26 and the driven members 27. Therefore, as shown in FIG. 9, the controller 30 corrects the command value of the speed for commanding the number of rotations of the motor based on the shift in the amount of movement such that the rotation is reversed at a timing earlier than the acquired command value. Thus, even when a command value that reverses the rotation direction of the motor 26a is acquired, the robot arm 21 operates smoothly. In this manner, the controller 30 corrects the command values based on the motions taught by the user through teaching operations, based on the shift in the amount of movement, so as to compensate for the deviation in transmission of the driving force. The controller 30 then stores the corrected command values in the storage, and operates the robot arms 21 and 22 based on the corrected command values.

For example, FIG. 9 shows an example in which a command value that changes linearly from negative to positive at a predetermined rate is acquired. In the command value before correction, the feedback value from the encoder indicating the actual rotation of the motor 26a is delayed with respect to the command value. In this regard, the controller 30 corrects the command value such that the command value becomes a large positive value at the timing at which the command value before correction changes from negative to positive. Therefore, the command value after correction changes from negative to positive at an earlier timing than the command value before correction. The controller 30 controls the rotation of the motor 26a using this command value after correction. Therefore, the delay is eliminated in the feedback value after correction.

### Control Process of Substrate Transport Method

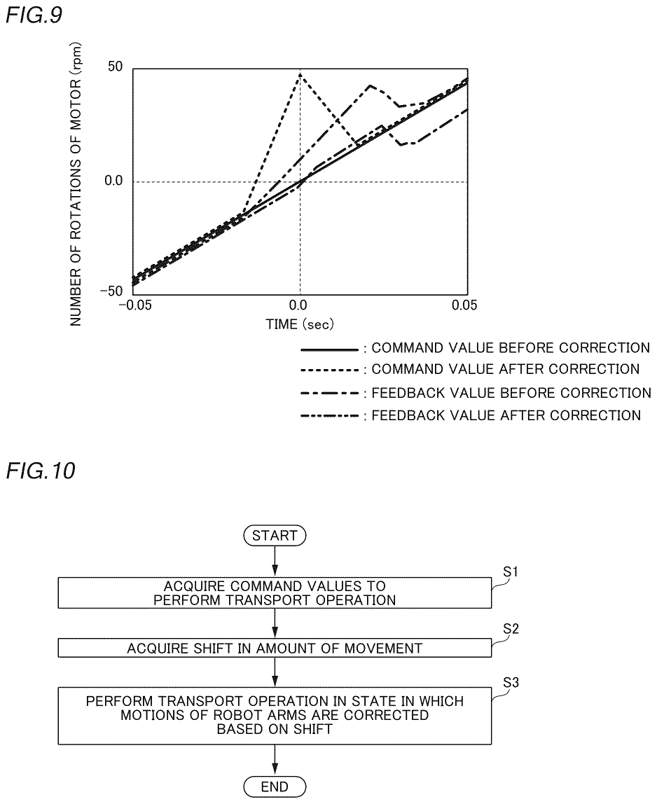

A control process of a substrate transport method by the substrate transport robot system 100 is now described with reference to FIG. 10. This control process of the substrate transport method is performed by the controller 30.

First, in step S1, command values are acquired to perform the transport operation. Then, in step S2, a shift in the amount of movement in the transport operation caused by a deviation in transmission between the drive 26 and the driven members 27 is acquired. Then, in step S3, the transport operation is performed in a state in which the motions of the robot arms 21 and 22 are corrected based on the acquired shift. Specifically, a correction amount is calculated based on the acquired shift. Then, based on the calculated correction amount, the command value acquired in step S1 is corrected. The command value acquired in step S1 includes a command value in the transport operation that is set in advance, and a command value for finely adjusting the motions of the robot arms 21 and 22 in the fine adjustment control based on detection by the detectors 60. In addition, either a control in step S1 or a control in step S2 may be performed first.

### Advantages of First Embodiment

The substrate transport robot system 100 includes the controller 30 configured or programmed to correct the motions of the robot arms 21 and 22 in the transport operation based on the shift in the amount of movement in the transport operation caused by the deviation in transmission between the drive 26 and the driven members 27. Accordingly, even when the deviation in transmission between the drive 26 and the driven members 27, such as backlash, occurs, a decrease in the positional accuracy of the transport operation can be reduced or prevented by correcting the motions of the robot arms 21 and 22 in the transport operation based on the shift in the amount of movement in the transport operation caused by the deviation in transmission. Therefore, a decrease in the accuracy of the motions of the robot arm 21 and the robot arm 22 can be reduced or prevented without restricting the movement direction in the transport operation as in a case of passing through a preset relay position, and thus a decrease in the accuracy of the motions of the robot arm 21 and the robot arm 22 can be reduced or prevented while an increase in the movement distance of the substrate 10 in the transport operation is reduced or prevented. Consequently, an increase in the time required for the transport operation can be reduced or prevented while a decrease in the accuracy of the substrate 10 transport operation is reduced or prevented.

The controller 30 is configured or programmed to correct the motions of the robot arms 21 and 22 based on the shift that occurs when the directions of the motions of the robot arms 21 and 22 are changed. Accordingly, even when the shift occurs in the amount of movement of the transport operation of the robot arms 21 and 22 due to backlash that occurs when the directions of the motions of the robot arms 21 and 22 are changed and lost motion, which is an error that occurs when positioning is performed from different directions, for example, the positional accuracy of the transport operation can be reduced by correcting the motions of the robot arms 21 and 22 based on the shift. Consequently, even when the directions of the motions of the robot arms 21 and 22 are changed, an increase in the time required for the transport operation can be reduced or prevented while a decrease in the accuracy of the substrate 10 transport operation is reduced or prevented.

The drive 26 includes the motor 26a, the motor 26b, and the motor 26c to perform rotational operation as drive sources. The controller 30 is configured or programmed to correct the motions of the robot arms 21 and 22 based on the shift that occurs when the rotation directions of the motors 26a, 26b, and 26c are reversed to change the directions of the motions of the robot arms 21 and 22. When the motors 26a, 26b, and 26c are used as drive sources for the motions of the robot arms 21 and 22, backlash and lost motion may occur when the rotation directions of the motors 26a, 26b, and 26c are reversed. Therefore, the motions of the robot arms 21 and 22 are corrected based on the shift that occurs when the rotation directions of the motors 26a, 26b, and 26c are reversed to change the directions of the motions of the robot arms 21 and 22 such that an increase in the time required for the transport operation can be effectively reduced or prevented while a decrease in the accuracy of the substrate 10 transport operation is effectively reduced or prevented.

The robot arms 21 and 22 have the plurality of degrees of freedom. The controller 30 is configured or programmed to correct the motions of the robot arms 21 and 22 for each of the plurality of degrees of freedom based on the shift acquired to correspond to each of the plurality of degrees of freedom of the motions of the robot arms 21 and 22. Accordingly, the motions of the robot arms 21 and 22 can be corrected for each of the plurality of degrees of freedom to correspond to the deviation in transmission between the drive 26 and the driven members 27 for each of the plurality of degrees of freedom of the motions of the robot arms 21 and 22, and thus a decrease in the accuracy of the substrate 10 transport operation can be further reduced or prevented.

The substrate transport robot system 100 includes the detectors 60 to detect at least one of the positions of the substrates 10 held by the substrate holding hands 23 and 24, the positions of the substrate holding hands 23 and 24, or the positions of the robot arms 21 and 22. The controller 30 is configured or programmed to acquire the shift based on the detection results obtained by the detectors 60. Accordingly, at least one of the positions of the substrates 10 held by the substrate holding hands 23 and 24, the positions of the substrate holding hands 23 and 24, or the positions of the robot arms 21 and 22 is detected such that the shift can be acquired while the substrate 10 is being transported. Therefore, even when the magnitude of the shift caused by the deviation in transmission between the drive 26 and the driven members 27 changes over time after the substrate transport robot system 100 is installed, the shift is periodically acquired such that the motions of the robot arms 21 and 22 can be corrected to correspond to the change in the shift. Therefore, the shift can be corrected more accurately, and thus a decrease in the accuracy of the substrate 10 transport operation can be further reduced or prevented.

The substrate transport robot system 100 includes the robot arm 21 serving as a first robot arm and the robot arm 22 serving as a second robot arm that are configured to operate separately from each other. The controller 30 is configured or programmed to correct the motions of the robot arms 21 and 22 based on the shift. Accordingly, a plurality of robot arms, the robot arms 21 and 22, are used to transport the substrates 10 such that the time required to transport a plurality of substrates 10 can be reduced. Furthermore, when the plurality of robot arms, the robot arms 21 and 22, are used to transport the substrates 10, the motion of each of the robot arms 21 and 22 is corrected such that an increase in the time required for the transport operation of each of the robot arms 21 and 22 can be reduced or prevented while a decrease in the accuracy of the transport operation of each of the robot arms 21 and 22 is reduced or prevented. Therefore, when the plurality of robot arms are used to transport the substrates 10, an increase in the time required for the transport operation can be effectively reduced or prevented while a decrease in the accuracy of the transport operation is reduced or prevented.

The controller 30 is configured or programmed to acquire the command values to control the transport operation. Furthermore, the controller 30 is configured or programmed to correct the motions of the robot arm 21 and the robot arm 22 by correcting the acquired command values based on the shift. Accordingly, even when the command values are acquired that cause a deviation in transmission between the drive 26 and the driven members 27, the command values can be corrected based on the shift, and thus the motions of the robot arm 21 and the robot arm 22 can be automatically corrected. Therefore, when the motions of the robot arms 21 and 22 in the transport operation are set, it is possible to automatically reduce or prevent a difference between the actual motions of the robot arms 21 and 22 and the motions according to the command values, without making settings that take into account shifts in advance. Consequently, the motions of the robot arms 21 and 22 in the transport operation can be easily set.

The substrate transport robot system 100 includes the detectors 60 to detect the substrate 10. The controller 30 is configured or programmed to perform the fine adjustment control to finely adjust the motions of the robot arms 21 and 22 in the transport operation based on the position of the substrate 10 detected by the detectors 60. Furthermore, the controller 30 is configured or programmed to correct the motions of the robot arms 21 and 22 based on the shift in the fine adjustment control. When the motions of the robot arms 21 and 22 are not corrected based on the shift, it is difficult to operate the robot arms 21 and 22 with a movement amount smaller than the shift due to the deviation in transmission between the drive 26 and the driven members 27. Therefore, when correction based on the shift is not performed, it is difficult to normally perform fine adjustment control such as finely changing the directions of the motions of the robot arms 21 and 22. In this regard, in the first embodiment, the controller 30 is configured or programmed to correct the motions of the robot arms 21 and 22 based on the shift in the fine adjustment control. Accordingly, the robot arms 21 and 22 can be operated with a movement amount smaller than the shift. Therefore, the motions of the robot arms 21 and 22 are corrected based on the shift such that the fine adjustment control can be performed normally.

### Second Embodiment

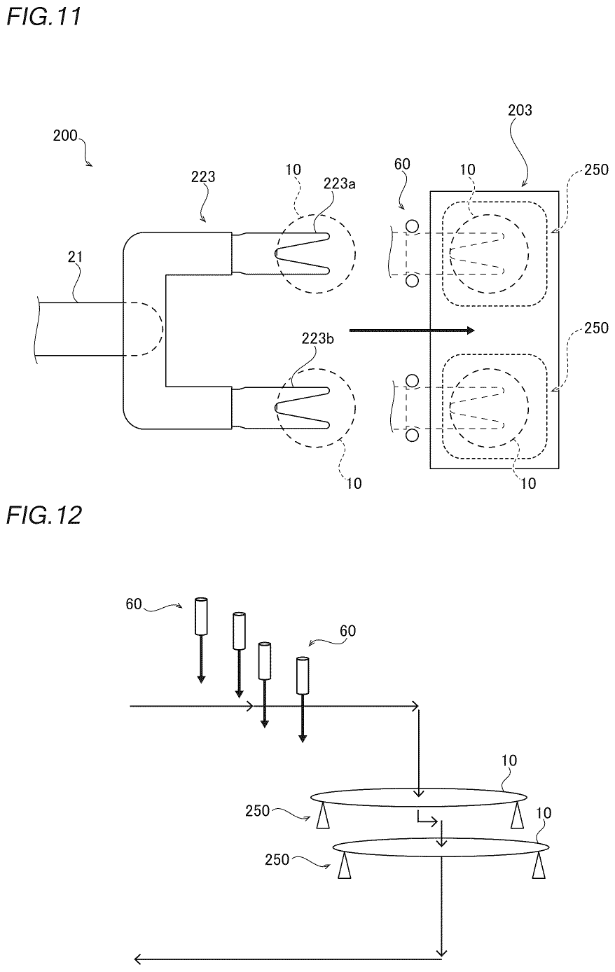

A substrate transport robot system 200 according to a second embodiment of the present disclosure is now described with reference to FIGS. 11 and 12. In the second embodiment, a pair of substrates 10 are held by one substrate holding hand 223. In the figures, portions having the same or similar configurations as those of the first embodiment are denoted by the same reference numerals, and description thereof is omitted.

As shown in FIG. 11, the substrate transport robot system 200 according to the second embodiment includes the substrate holding hand 223 that holds a pair of substrates 10. The substrate holding hand 223 is attached to a distal end of a robot arm 21. The substrate holding hand 223 holds a pair of substrates 10. Specifically, the substrate holding hand 223 includes a pair of holders 223a and 223b. Each of the holders 223a and 223b holds one substrate 10. The holders 223a and 223b are thin support plates that each support the substrate 10 from below, similarly to the holder 23a according to the first embodiment.

In the substrate holding hand 223, the pair of substrates 10 are held while being aligned right and left along the horizontal plane. The holders 223a and 223b are integral and unitary with each other. That is, in the substrate holding hand 223, the pair of substrates 10 are held in a state in which the relative positional relationship is fixed. The substrate transport robot system 200 transports the pair of substrates 10 held by the substrate holding hand 223 integrally by operating the robot arm 21.

The substrate transport robot system 200 performs transport operation with respect to a processing module 203 that processes the substrates 10, similarly to the first embodiment. For example, each of a plurality of processing modules 203 processes two substrates 10 at a time. That is, in each of the plurality of processing modules 203, two substrates 10 are placed on mounts 250. In the second embodiment, a load lock 102 includes a pair of mounts that are substantially equal in height, which is a vertical position at the placement position. The substrate holding hand 223 collectively holds the substrates 10 placed on the pair of mounts of the load lock 102. Each of the plurality of processing modules 203 includes a pair of mounts 250 having different placement position heights. In the plan view, the positional relationship between the pair of mounts 250 is similar to the positional relationship between the pair of mounts of the load lock 102. The substrate transport robot system 200 transports a pair of substrates 10 together between the two mounts of the load lock 102 and the two mounts 250 of each of the processing modules 203.

In the second embodiment, detectors 60 detect each of the pair of substrates 10 held by the substrate holding hand 223. Four detectors 60 are arranged for the mounts 250 on which a pair of substrates 10 are placed.

### Details of Control of Transport Operation by Controller

In the second embodiment, a controller 30 controls the transport operation of the robot arm 21, including the placement operation to place the pair of substrates 10 on the mounts 250, and the holding operation to hold the pair of substrates 10 from the mounts 250. In the transport operation to transport a pair of substrates 10, similarly to the first embodiment, the controller 30 acquires a shift in the amount of movement in the transport operation based on the detection results obtained by the detectors 60, and corrects the motion of the robot arm 21 in the transport operation based on the shift in the amount of movement in the transport operation.

As shown in FIG. 12, in the second embodiment, the controller 30 performs a fine adjustment control to finely adjust the motion of the robot arm 21 in the transport operation to transport a pair of substrates 10 based on the detection results detected by the detectors 60. Then, the controller 30 corrects the motion of the robot arm 21 in the fine adjustment control.

In the second embodiment, the controller 30 calculates the misalignment of each of a pair of substrates 10 held by the substrate holding hand 223 based on the detection results of the detectors 60, and performs the fine adjustment control to correct a command value to compensate for the misalignment.

When the heights of the placement positions of the pair of mounts 250 are different from each other, the controller 30 controls the transport operation of the robot arm 21 such that the pair of substrates 10 held by the substrate holding hand 223 are placed one by one sequentially and separately on the mounts 250. Specifically, similarly to the first embodiment, the controller 30 corrects the command value to compensate for the alignment of the substrate 10 based on the detection results of the detectors 60 while the substrate 10 is being transported toward the mount 250. In the second embodiment, the controller 30 controls the motion of the robot arm 21 based on the corrected command value such that the substrate 10 is placed on one mount 250 having a relatively high placement position, and then finely adjusts the motion of the robot arm 21 such that the substrate 10 is placed on the other mount 250 having a relatively low placement position. Then, the controller 30 places the substrate 10 on the other mount 50 by lowering the substrate holding hand 223 while aligning the position of the substrate 10 on the horizontal plane with the position of the other mount 250. In such a case, when the rotation directions of motors 26a, 26b, and 26c of a drive 26 are reversed when the fine adjustment control is performed, the controller 30 further corrects the command value corrected based on the detection results, based on correction amounts calculated from the shifts, similarly to the first embodiment. Thus, each of the pair of substrate 10 is placed on the mount 250 with the position of the substrate 10 on the horizontal plane with respect to the mount 250 accurately fine-tuned.

Even in the holding operation to hold the substrates 10 placed on the pair of mounts 250 having different heights, the misalignment of the placed substrates 10 may be detected, and the substrates 10 may be held sequentially while the fine adjustment control is performed based on the detected misalignment. Even during the normal transport to transport the pair of substrates 10 according to a preset command value, the controller 30 corrects the command value based on the correction amounts calculated from the shifts in the amount of movement when motions are included in which the rotation directions of the motor 26a, the motor 26b, and the motor 26c of the drive 26 are reversed, similarly to the first embodiment. The remaining configurations of the second embodiment are similar to those of the first embodiment.

### Advantages of Second Embodiment

According to the second embodiment, as described above, the substrate holding hand 223 includes the plurality of holders 223a and 223b being integral and unitary with each other and configured to hold the plurality of substrates 10, respectively. The controller 30 is configured or programmed to correct the motion of the robot arm 21 based on the shift in the transport operation of the robot arm 21, including at least one of the placement operation to place the plurality of substrates 10 on the mounts 250 or the holding operation to hold the plurality of substrates 10 from the mounts 250, respectively. When a plurality of substrates 10 are transported together by the holders 223a and 223b that are integral and unitary with each other, the substrates 10 may be placed or held while the position of the substrate holding hand 223 is finely adjusted to correspond to the position of each of the plurality of substrates 10. In such a case, a control is performed to finely adjust the motion of the robot arm 21 to correspond to the position of each of the plurality of substrates 10. Therefore, the motion of the robot arm 21 is corrected based on the shift in the transport operation to transport the plurality of substrates 10 such that an increase in the time required for the transport operation can be effectively reduced or prevented while a decrease in the accuracy of the transport operation to transport the substrates 10 is effectively reduced or prevented, even when the motion of the robot arm 21 is finely adjusted to transport the plurality of substrates 10. The remaining advantages of the second embodiment are similar to those of the first embodiment.

### Modified Examples

The embodiments disclosed this time must be considered as illustrative in all points and not restrictive. The scope of the present disclosure is not shown by the above description of the embodiments but by the scope of claims for patent, and all modifications (modified examples) within the meaning and scope equivalent to the scope of claims for patent are further included.

For example, while the example in which the controller 30 corrects the motions of the robot arms 21 and 22 based on the acquired shift in the amount of movement when the plurality of substrates 10 are separately placed on the mounts 50 and 250 of the processing modules 103 and 203 has been shown in the aforementioned first and second embodiments, the present disclosure is not limited to this. In the present disclosure, the controller may correct the motions of the robot arms based on the acquired shift in the amount of movement when the substrates are placed on the mounts of the load lock. Furthermore, while the example in which the substrates 10 are placed on the pair of mounts 250 having different placement position heights has been shown in the second embodiment, the motions of the robot arms may be corrected based on the shift in the amount of movement even when a plurality of substrates are transported separately to a plurality of mounts having substantially the same placement position heights.

While the example in which the substrate 10 is placed on each of the pair of mounts 250 having different placement position heights has been shown in the aforementioned second embodiment, the present disclosure is not limited to this. In the present disclosure, the placement position of the mount may be changed when each of the pair of substrates is placed. For example, while the pair of substrates are held by the substrate holding hand, the substrate may be placed on the mount by moving a pin-shaped member of the mount upward. In such a case, too, the substrate transport robot system according to the present disclosure corrects the motion of the robot arm based on the shift in the amount of movement in order to position the substrate directly above the mount.

While the example in which in the substrate holding hand 223, a pair of substrates 10 are aligned right and left along the horizontal plane has been shown in the aforementioned second embodiment, the present disclosure is not limited to this. In the present disclosure, in the substrate holding hand, the plurality of substrates may be aligned right and left, not along the horizontal plane, but with a vertical offset. Alternatively, the substrate holding hand may hold a plurality of substrates aligned along the vertical direction, rather than aligned right and left. The number of substrates held by the substrate holding hand may be one, or three or more. Each of the holders of the substrate holding hand may have a U-shape with a bifurcated distal end or may have a plate shape with an unbranched distal end. Furthermore, the substrate holding hand may not be a passive-type end effector.

While the example in which the transport robot 20 includes the robot arm 21 serving as a first robot arm and the robot arm 22 serving as a second robot arm that operate separately from each other has been shown in each of the aforementioned first and second embodiments, the present disclosure is not limited to this. In the present disclosure, the transport robot may include only one robot arm or may include three or more robot arms. Furthermore, the two robot arms may share a portion of the arm. In other words, the two robot arms may be connected to a common member that rotates with respect to the base.

While the example in which the detectors 60 that detect the substrate 10 include transmissive laser sensors has been shown in each of the aforementioned first and second embodiments, the present disclosure is not limited to this. In the present disclosure, the detectors may include reflective laser sensors or imagers such as cameras that capture external images. That is, the amount of deviation of the substrate may be acquired based on the captured external images. Alternatively, the detectors may be arranged on the transport robot of the substrate transport robot system. For example, the detectors may be arranged on the base to which the robot arms are connected. Alternatively, the detectors may be arranged on the robot arms or the substrate holding hands.

While the example in which the shift in the amount of movement is acquired based on the detection results of the detectors 60 that detect the substrate 10 has been shown in each of the aforementioned first and second embodiments, the present disclosure is not limited to this. In the present disclosure, the detectors may detect at least one of the position of the substrate, the position of the substrate holding hand, or the position of the robot arm.

While the example in which the controller 30, which is a robot controller that controls the motions of the robot arms 21 and 22, acquires the shift in the amount of movement and corrects the motions of the robot arms 21 and 22 has been shown in each of the aforementioned first and second embodiments, the present disclosure is not limited to this. In the present disclosure, the shift in the amount of movement may be acquired by a control device separate from the robot controller. For example, a preset shift in the amount of movement may be stored in a storage of the substrate transport robot system at the time of shipment of the substrate transport robot system. Alternatively, the motions of the robot arms 21 and 22 may be corrected based on the acquired shift by a control device separate from the robot controller. That is, the command values may be corrected by a control device separate from the robot controller, and the corrected command values may be acquired by the robot controller.

While the example in which the substrate transport robot systems 100 and 200 transport the substrates 10 in the transport chamber 104 maintained at a predetermined vacuum level has been shown in the aforementioned first and second embodiments, the present disclosure is not limited to this. In the present disclosure, the substrates may be transported at normal pressure.

While the example in which each of the plurality of processing modules 203 includes the two mounts 250 having different placement position heights has been shown in the aforementioned second embodiment, the present disclosure is not limited to this. In the present disclosure, some or all of the plurality of processing modules may include a plurality of mounts having substantially the same placement position heights.

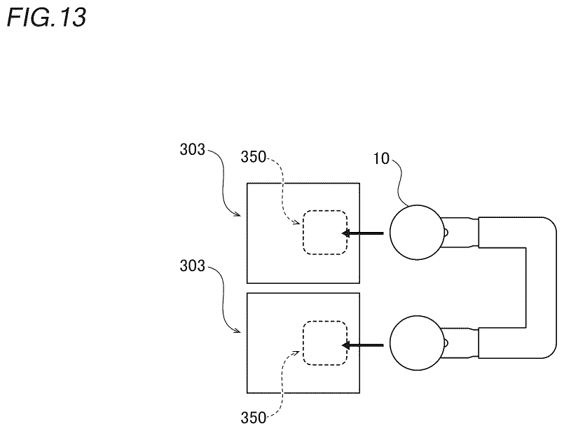

As in a substrate processing system according to a modified example shown in FIG. 13, a pair of processing modules 303 that each process one substrate 10 may be arranged adjacent to each other. In such a case, the heights of the placement positions of mounts 350 of the pair of adjacent processing modules 303 may be different from each other. That is, the placement position of one of the mounts 350 of the pair of adjacent processing modules 303 may be higher than the placement position of the other of the mounts 350. Alternatively, the heights of the mounts of the pair of adjacent processing modules may be equal to each other.

The functionality of the elements disclosed herein may be implemented using circuitry or processing circuitry which includes general purpose processors, special purpose processors, integrated circuits, ASICs (“Application Specific Integrated Circuits”), conventional circuitry and/or combinations thereof which are configured or programmed to perform the disclosed functionality. Processors are considered processing circuitry or circuitry as they include transistors and other circuitry therein. The processor may be a programmed processor which executes a program stored in a memory. In the disclosure, the circuitry, units, or means are hardware that carry out or are programmed to perform the recited functionality. The hardware may be any hardware disclosed herein or otherwise known which is programmed or configured to carry out the recited functionality. When the hardware is a processor which may be considered a type of circuitry, the circuitry, means, or units are a combination of hardware and software, the software being used to configure the hardware and/or processor.

### Aspects

It will be appreciated by those skilled in the art that the exemplary embodiments described above are specific examples of the following aspects.

### Item 1

A substrate transport robot system comprising:
a substrate holding hand to hold a substrate;
a robot arm attached to the substrate holding hand;
a drive to serve as a drive source to operate the robot arm in transport operation of the robot arm, the transport operation including at least one of placement operation to place the substrate on a mount or holding operation to hold the substrate from the mount;
a driven member to transmit a driving force of the drive to operate the robot arm; and
a controller configured or programmed to correct a motion of the robot arm in the transport operation based on a shift in an amount of movement in the transport operation caused by a deviation in transmission between the drive and the driven member.

### Item 2

The substrate transport robot system according to item 1, wherein the controller is configured or programmed to correct the motion of the robot arm based on the shift that occurs when a direction of the motion of the robot arm is changed.

### Item 3

The substrate transport robot system according to item 2, wherein
the drive includes a motor to perform rotational operation as the drive source; and
the controller is configured or programmed to correct the motion of the robot arm based on the shift that occurs when a rotation direction of the motor is reversed to change the direction of the motion of the robot arm.

### Item 4

The substrate transport robot system according to any one of items 1 to 3, wherein
the robot arm has a plurality of degrees of freedom; and
the controller is configured or programmed to correct the motion of the robot arm for each of the plurality of degrees of freedom based on the shift acquired to correspond to each of the plurality of degrees of freedom of the motion of the robot arm.

### Item 5

The substrate transport robot system according to any one of items 1 to 4, further comprising:
a detector to detect at least one of a position of the substrate held by the substrate holding hand, a position of the substrate holding hand, or a position of the robot arm; wherein
the controller is configured or programmed to acquire the shift based on a detection result obtained by the detector.

### Item 6

The substrate transport robot system according to any one of items 1 to 5, wherein
the substrate holding hand includes a plurality of holders integral and unitary with each other to hold a plurality of substrates, respectively; and
the controller is configured or programmed to correct the motion of the robot arm based on the shift in the transport operation of the robot arm, the transport operation including at least one of the placement operation to place each of the plurality of substrates on the mount or the holding operation to hold each of the plurality of substrates from the mount.

### Item 7

The substrate transport robot system according to any one of items 1 to 6, wherein
the robot arm includes a first robot arm and a second robot arm configured to operate separately from each other; and
the controller is configured or programmed to correct a motion of each of the first robot arm and the second robot arm based on the shift.

### Item 8

The substrate transport robot system according to any one of items 1 to 7, wherein the controller is configured or programmed to:
acquire a command value to control the transport operation; and
correct the motion of the robot arm by correcting an acquired command value based on the shift.

### Item 9

The substrate transport robot system according to any one of items 1 to 8, further comprising:
a detector to detect the substrate; wherein
the controller is configured or programmed to:
   perform a fine adjustment control to finely adjust the motion of the robot arm in the transport operation based on a position of the substrate detected by the detector; and
   correct the motion of the robot arm based on the shift in the fine adjustment control.

1. A substrate transport robot system comprising:
a substrate holding hand to hold a substrate;
a robot arm attached to the substrate holding hand;
a drive to serve as a drive source to operate the robot arm in transport operation of the robot arm, the transport operation including at least one of placement operation to place the substrate on a mount or holding operation to hold the substrate from the mount;
a driven member to transmit a driving force of the drive to operate the robot arm; and
a controller configured or programmed to correct a motion of the robot arm in the transport operation based on a shift in an amount of movement in the transport operation caused by a deviation in transmission between the drive and the driven member.

2. The substrate transport robot system according to claim 1, wherein the controller is configured or programmed to correct the motion of the robot arm based on the shift that occurs when a direction of the motion of the robot arm is changed.

3. The substrate transport robot system according to claim 2, wherein
the drive includes a motor to perform rotational operation as the drive source; and
the controller is configured or programmed to correct the motion of the robot arm based on the shift that occurs when a rotation direction of the motor is reversed to change the direction of the motion of the robot arm.

4. The substrate transport robot system according to claim 1, wherein
the robot arm has a plurality of degrees of freedom; and
the controller is configured or programmed to correct the motion of the robot arm for each of the plurality of degrees of freedom based on the shift acquired to correspond to each of the plurality of degrees of freedom of the motion of the robot arm.

5. The substrate transport robot system according to claim 1, further comprising:
a detector to detect at least one of a position of the substrate held by the substrate holding hand, a position of the substrate holding hand, or a position of the robot arm; wherein
the controller is configured or programmed to acquire the shift based on a detection result obtained by the detector.

6. The substrate transport robot system according to claim 1, wherein
the substrate holding hand includes a plurality of holders integral and unitary with each other to hold a plurality of substrates, respectively; and
the controller is configured or programmed to correct the motion of the robot arm based on the shift in the transport operation of the robot arm, the transport operation including at least one of the placement operation to place each of the plurality of substrates on the mount or the holding operation to hold each of the plurality of substrates from the mount.

7. The substrate transport robot system according to claim 1, wherein
the robot arm includes a first robot arm and a second robot arm configured to operate separately from each other; and
the controller is configured or programmed to correct a motion of each of the first robot arm and the second robot arm based on the shift.

8. The substrate transport robot system according to claim 1, wherein the controller is configured or programmed to:
acquire a command value to control the transport operation; and
correct the motion of the robot arm by correcting an acquired command value based on the shift.

9. The substrate transport robot system according to claim 1, further comprising:
a detector to detect the substrate; wherein
the controller is configured or programmed to:
perform a fine adjustment control to finely adjust the motion of the robot arm in the transport operation based on a position of the substrate detected by the detector; and
correct the motion of the robot arm based on the shift in the fine adjustment control.
